(19) United States
(12) Patent Application Publication
(10) Pub. No.: US 2025/0357109 A1
(43) Pub. Date: Nov. 20, 2025

(54) BOTTOM-UP GAP FILL USING NON-CONFORMAL POISONING

(71) Applicant: Applied Materials, Inc., Santa Clara, CA (US)

(72) Inventors: Sukrant Dhawan, Santa Clara, CA (US); Supriya Ghosh, San Jose, CA (US); Bhaskar Soman, San Jose, CA (US); Susmit Singha Roy, Campbell, CA (US); Akhil Singhal, Portland, OR (US); Abhijit Basu Mallick, Sunnyvale, CA (US)

(73) Assignee: Applied Materials, Inc., Santa Clara, CA (US)

(21) Appl. No.: 18/666,401

(22) Filed: May 16, 2024

(51) Int. Cl. H01L 21/02; C23C 16/02; C23C 16/04; C23C 16/24

(52) U.S. Cl. CPC H01L 21/0228; C23C 16/0272; C23C 16/045; C23C 16/24; H01L 21/02126; H01L 21/02274

(57) ABSTRACT

Exemplary processing methods may include providing a carbon-containing precursor to a processing region of a semiconductor processing chamber. A substrate may be disposed in the processing region. The substrate may define a feature. The methods may include contacting the substrate with the carbon-containing precursor. The contacting may form a carbon-containing material on the substrate that partially lines the feature. The methods may include performing a silicon-containing atomic layer deposition (ALD) process. The silicon-containing ALD process may deposit a silicon-containing material at a bottom portion of the feature. The methods may include repeating the operations to fill the feature with silicon-containing material.

### TECHNICAL FIELD

The present technology relates to semiconductor processing. More specifically, the present technology relates to methods of bottom-up gap filling of silicon-containing materials using non-conformal poisoning.

### BACKGROUND

Integrated circuits are made possible by processes which produce intricately patterned material layers on substrate surfaces. Producing patterned material on a substrate requires controlled methods of formation and removal of exposed material. As device sizes continue to shrink, material formation may affect subsequent operations. For example, in gap filling operations a material may be formed or deposited to fill a trench or other feature formed on a semiconductor substrate. As features may be characterized by higher aspect ratios and reduced critical dimensions, these filling operations may be challenged. For example, as the deposition may occur at the top and along sidewalls of the feature, continued deposition may pinch off the feature including between sidewalls within the feature, and may produce voids within the feature. This can impact device performance and subsequent processing operations.

Thus, there is a need for improved systems and methods that can be used to produce high quality devices and structures. These and other needs are addressed by the present technology.

### SUMMARY

Exemplary processing methods may include providing a carbon-containing precursor to a processing region of a semiconductor processing chamber. A substrate may be disposed in the processing region. The substrate may define a feature. The methods may include contacting the substrate with the carbon-containing precursor. The contacting may form a carbon-containing material on the substrate that partially lines the feature. The methods may include performing a silicon-containing atomic layer deposition (ALD) process. The silicon-containing ALD process may deposit a silicon-containing material at a bottom portion of the feature. The methods may include repeating the operations to fill the feature with silicon-containing material.

In some embodiments, the carbon-containing precursor may be or include a hydrocarbon. The feature may be characterized by an aspect ratio of greater than or about 10:1. The feature may be characterized by a depth of greater than or about 1 μm. The methods may include forming plasma effluents of the carbon-containing precursor. The carbon-containing material may be discontinuous. The silicon-containing ALD process may be plasma-enhanced. The silicon-containing ALD process may remove the carbon-containing material. The silicon-containing material may not be deposited on the carbon-containing material. The silicon-containing material may fill the feature from bottom-up.

Some embodiments of the present technology may encompass semiconductor processing methods. The methods may include i) providing a carbon-containing precursor to a processing region of a semiconductor processing chamber. A substrate may be disposed in the processing region. The substrate may define a feature. The methods may include ii) forming plasma effluents of the carbon-containing precursor. The methods may include iii) contacting the substrate with the carbon-containing precursor. The contacting may form a carbon-containing material that may be discontinuous on the substrate that partially lines the feature. The methods may include iv) performing a silicon-containing atomic layer deposition (ALD) process. The silicon-containing ALD process may deposit a silicon-containing material at a bottom portion of the feature. The silicon-containing ALD process may include providing a silicon-containing precursor to the processing region, forming plasma effluents of the silicon-containing precursor, contacting the substrate with the silicon-containing precursor, providing an oxygen-containing precursor to the processing region, forming plasma effluents of the oxygen-containing precursor, and contacting the substrate with the oxygen-containing precursor.

In some embodiments, the feature may be characterized by a width of less than or about 100 nm. The silicon-containing material may be selectively deposited on sidewalls of the feature. Contacting the substrate with the oxygen-containing precursor may remove the carbon-containing material. The methods may include v) repeating operations i) through iv) to fill the feature with the silicon-containing material for a plurality of cycles. The methods may include reducing a flow rate of the carbon-containing precursor during subsequent cycles. The silicon-containing ALD process may further include purging the silicon-containing precursor prior to providing the oxygen-containing precursor.

Some embodiments of the present technology may encompass semiconductor processing methods. The methods may include i) providing a hydrocarbon precursor to a processing region of a semiconductor processing chamber. A substrate may be disposed in the processing region. The substrate may define a feature characterized by an aspect ratio greater than or about 30:1. The methods may include ii) contacting the substrate with the hydrocarbon precursor. The contacting may form a carbon-containing material that is non-conformal on the substrate that partially lines the feature. The methods may include iii) performing a silicon-containing atomic layer deposition (ALD) process. The silicon-containing ALD process may deposit a silicon-containing material at a bottom portion of the feature. The methods may include iv) repeating operations i) through iii) to fill the feature with silicon-containing material.

In some embodiments, the hydrocarbon precursor may be or include hexane (C₆H₁₄) or acetylene (C₂H₂). The silicon-containing ALD process may include contacting the substrate with an oxygen-containing precursor. The contacting may remove the carbon-containing material.

Such technology may provide numerous benefits over conventional systems and techniques. For example, by performing a poisoning operation, an amount of poisoning material may be formed that partially lines the feature and reduces or prevents silicon-containing material deposition on the poisoning material. Additionally, the deposition of silicon-containing material may at least partially consume or remove the poisoning material. By cycling these operations, a feature may be gap filled with silicon-containing material while reducing or preventing formation of a seam or a void. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic cross-sectional view of an exemplary processing chamber according to some embodiments of the present technology.

FIG. 2 shows exemplary operations in a processing method according to some embodiments of the present technology.

FIGS. 3A-3E show schematic cross-sectional views of a substrate during a processing according to some embodiments of the present technology.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Silicon-containing materials may be used in semiconductor device manufacturing for a number of structures and processes. Some examples include using silicon-containing materials as a sacrificial material. For example, the silicon-and-oxygen-containing material may be used as, but is not limited to, a dummy gate material or as a trench fill material. In other examples, silicon-containing materials may be used in deep trench isolation (DTI) structures. In gap filling operations, some processing may utilize plasma-enhanced deposition under process conditions to increase the directionality of the deposition, which may allow the deposited material to better fill features on the substrate.

As feature sizes continue to shrink, plasma-enhanced depositions may be challenged for narrow features, which may be further characterized by higher aspect ratios. For example, pinching-off in the feature may more readily occur due to deposition on sidewalls of the feature, which in small feature sizes may further restrict flow and deposition into the feature, and may produce seams or voids in the feature. Conventional technologies have attempted to address the formation of seams or voids by utilizing flowable materials to fill trenches or features. However, to convert the flowable materials to oxide materials, an operation such as a steam anneal may be necessary. In many applications, a steam anneal to cure the flowable materials may be well above thermal budgets. Other technologies have attempted to perform cycles of deposition and etching to remove material from sidewalls of the feature. However, the cycles of deposition and etching may be lengthy and may damage other exposed materials during the etching.

The present technology may overcome these limitations by performing a poisoning operation prior to and/or during gap filling. The poisoning may form a non-conformal and discontinuous poisoning material that partially extends into the features to be gap filled. The subsequent deposition may not form material on the poisoning material, which may limit sidewall coverage and prevent or reduce clogging or pinching-off of the feature. This limited sidewall coverage may result in a bottom-up, zipper-like gap fill that may selectively deposit silicon-containing material towards a bottom portion of the feature. By repeating these operations for a number of cycles, a feature may be filled with silicon-containing material while reducing or preventing the formation of a seam or a void.

After describing general aspects of a chamber according to some embodiments of the present technology in which gap filling operations discussed below may be performed, specific methodology may be discussed. It is to be understood that the present technology is not intended to be limited to the specific films, chambers or processes discussed, as the techniques described may be used to improve a number of film formation processes, and may be applicable to a variety of processing chambers and operations.

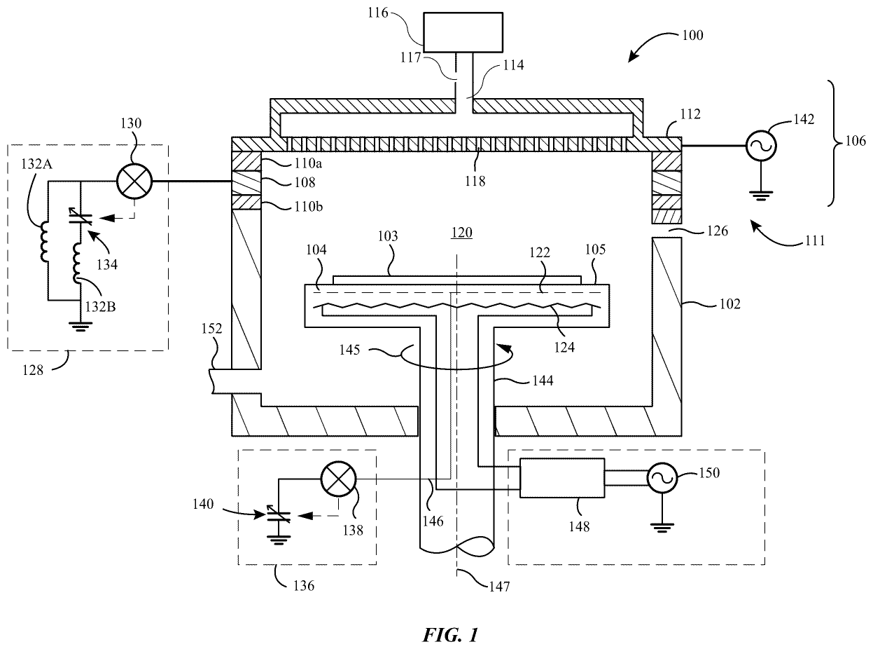

FIG. 1 shows a cross-sectional view of an exemplary processing chamber 100 according to some embodiments of the present technology. The figure may illustrate an overview of a system incorporating one or more aspects of the present technology, and/or which may perform one or more deposition or other processing operations according to embodiments of the present technology. Additional details of chamber 100 or methods performed may be described further below. Chamber 100 may be utilized to form film layers according to some embodiments of the present technology, although it is to be understood that the methods may similarly be performed in any chamber within which film formation may occur. The processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. The substrate support 104 may be rotatable, as indicated by the arrow 145, along an axis 147, where a shaft 144 of the substrate support 104 may be located. Alternatively, the substrate support 104 may be lifted to rotate as necessary during a deposition process.

A plasma profile modulator 111 may be disposed in the processing chamber 100 to control plasma distribution across the substrate 103 disposed on the substrate support 104. The plasma profile modulator 111 may include a first electrode 108 that may be disposed adjacent to the chamber body 102, and may separate the chamber body 102 from other components of the lid assembly 106. The first electrode 108 may be part of the lid assembly 106, or may be a separate sidewall electrode. The first electrode 108 may be an annular electrode. The first electrode 108 may be a continuous loop around a circumference of the processing chamber 100 surrounding the processing volume 120, or may be discontinuous at selected locations if desired. The first electrode 108 may also be a perforated electrode, such as a perforated ring or a mesh electrode, or may be a plate electrode, such as, for example, a secondary gas distributor.

One or more isolators 110a, 110b, which may be a dielectric material such as a ceramic or metal oxide, for example aluminum oxide and/or aluminum nitride, may contact the first electrode 108 and separate the first electrode 108 electrically and thermally from a gas distributor 112, also referred to as a faceplate, and from the chamber body 102. The gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the processing chamber. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1, or the gas distributor 112 may be coupled with ground in some embodiments.

The first electrode 108 may be coupled with a first tuning circuit 128 that may control a ground pathway of the processing chamber 100. The first tuning circuit 128 may include a first electronic sensor 130 and a first electronic controller 134. The first electronic controller 134 may be or include a variable capacitor or other circuit elements. The first tuning circuit 128 may be or include one or more inductors 132. The first tuning circuit 128 may be any circuit that enables variable or controllable impedance under the plasma conditions present in the processing volume 120 during processing. In some embodiments as illustrated, the first tuning circuit 128 may include a first circuit leg and a second circuit leg coupled in parallel between ground and the first electronic sensor 130. The first circuit leg may include a first inductor 132A. The second circuit leg may include a second inductor 132B coupled in series with the first electronic controller 134. The second inductor 132B may be disposed between the first electronic controller 134 and a node connecting both the first and second circuit legs to the first electronic sensor 130. The first electronic sensor 130 may be a voltage or current sensor and may be coupled with the first electronic controller 134, which may afford a degree of closed-loop control of plasma conditions inside the processing volume 120.

A second electrode 122 may be coupled with the substrate support 104. The second electrode 122 may be embedded within the substrate support 104 or coupled with a surface of the substrate support 104. The second electrode 122 may be a plate, a perforated plate, a mesh, a wire screen, or any other distributed arrangement of conductive elements. The second electrode 122 may be a tuning electrode, and may be coupled with a second tuning circuit 136 by a conduit 146, for example a cable having a selected resistance, such as 50 ohms, for example, disposed in the shaft 144 of the substrate support 104. The second tuning circuit 136 may have a second electronic sensor 138 and a second electronic controller 140, which may be a second variable capacitor. The second electronic sensor 138 may be a voltage or current sensor, and may be coupled with the second electronic controller 140 to provide further control over plasma conditions in the processing volume 120.

A third electrode 124, which may be a bias electrode and/or an electrostatic chucking electrode, may be coupled with the substrate support 104. The third electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be an RF bias power.

The lid assembly 106 and substrate support 104 of FIG. 1 may be used with any processing chamber for plasma or thermal processing. In operation, the processing chamber 100 may afford real-time control of plasma conditions in the processing volume 120. The substrate 103 may be disposed on the substrate support 104, and process gases may be flowed through the lid assembly 106 using an inlet 114 according to any desired flow plan. Gases may exit the processing chamber 100 through an outlet 152. Electric power may be coupled with the gas distributor 112 to establish a plasma in the processing volume 120. The substrate may be subjected to an electrical bias using the third electrode 124 in some embodiments.

Upon energizing a plasma in the processing volume 120, a potential difference may be established between the plasma and the first electrode 108. A potential difference may also be established between the plasma and the second electrode 122. The electronic controllers 134, 140 may then be used to adjust the flow properties of the ground paths represented by the two tuning circuits 128 and 136. A set point may be delivered to the first tuning circuit 128 and the second tuning circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Each of the tuning circuits 128, 136 may have a variable impedance that may be adjusted using the respective electronic controllers 134, 140. Where the electronic controllers 134, 140 are variable capacitors, the capacitance range of each of the variable capacitors, and the inductances of the first inductor 132A and the second inductor 132B, may be chosen to provide an impedance range. This range may depend on the frequency and voltage characteristics of the plasma, which may have a minimum in the capacitance range of each variable capacitor. Hence, when the capacitance of the first electronic controller 134 is at a minimum or maximum, impedance of the first tuning circuit 128 may be high, resulting in a plasma shape that has a minimum aerial or lateral coverage over the substrate support. When the capacitance of the first electronic controller 134 approaches a value that minimizes the impedance of the first tuning circuit 128, the aerial coverage of the plasma may grow to a maximum, effectively covering the entire working area of the substrate support 104. As the capacitance of the first electronic controller 134 deviates from the minimum impedance setting, the plasma shape may shrink from the chamber walls and aerial coverage of the substrate support may decline. The second electronic controller 140 may have a similar effect, increasing and decreasing aerial coverage of the plasma over the substrate support as the capacitance of the second electronic controller 140 may be changed.

The electronic sensors 130, 138 may be used to tune the respective circuits 128, 136 in a closed loop. A set point for current or voltage, depending on the type of sensor used, may be installed in each sensor, and the sensor may be provided with control software that determines an adjustment to each respective electronic controller 134, 140 to minimize deviation from the set point. Consequently, a plasma shape may be selected and dynamically controlled during processing. It is to be understood that, while the foregoing discussion is based on electronic controllers 134, 140, which may be variable capacitors, any electronic component with adjustable characteristic may be used to provide tuning circuits 128 and 136 with adjustable impedance.

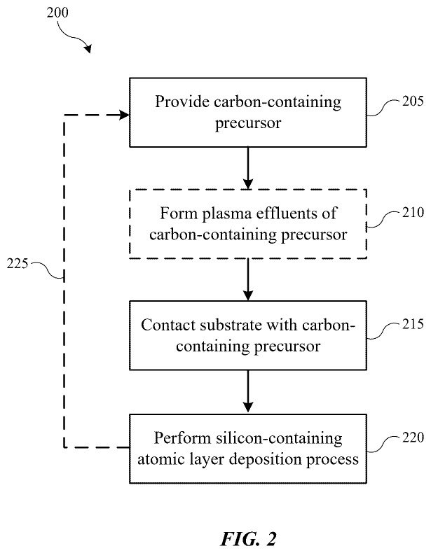

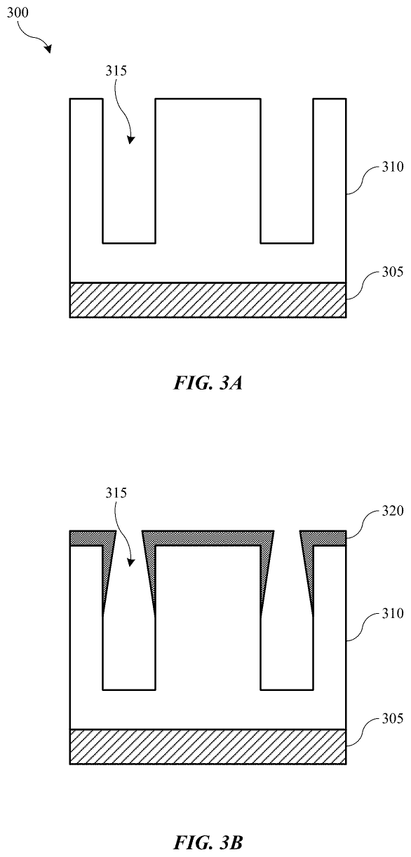

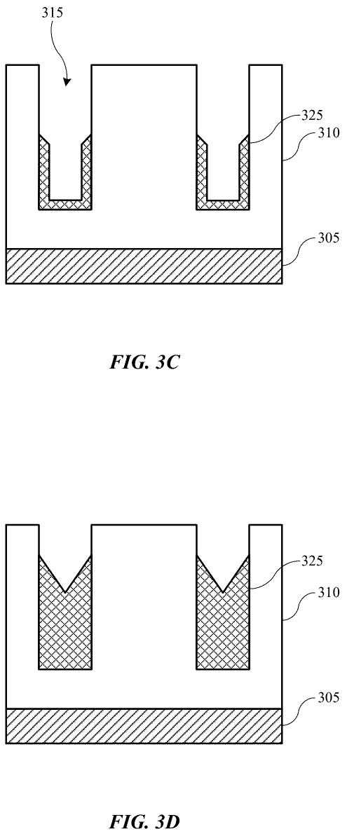

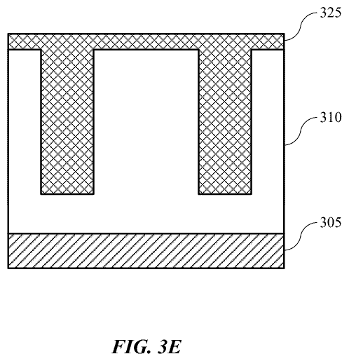

Processing chamber 100 may be utilized in some embodiments of the present technology for processing methods that may include gap filling materials for semiconductor structures. It is to be understood that the chamber described is not to be considered limiting, and any chamber that may be configured to perform operations as described may be similarly used. FIG. 2 shows exemplary operations in a processing method 200 according to some embodiments of the present technology. The method may be performed in a variety of processing chambers and on one or more mainframes or tools, including processing chamber 100 described above. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated. Method 200 may describe operations shown schematically in FIGS. 3A-3E, the illustrations of which will be described in conjunction with the operations of method 200. It is to be understood that the figures illustrate only partial schematic views, and a substrate may contain any number of additional materials and features having a variety of characteristics and aspects as illustrated in the figures.

Method 200 may include additional operations prior to initiation of the listed operations. For example, additional processing operations may include forming structures on a substrate, which may include both forming and removing material. For example, transistor structures, memory structures, or any other structures may be formed. Prior processing operations may be performed in the chamber in which method 200 may be performed, or processing may be performed in one or more other processing chambers prior to delivering the substrate into the semiconductor processing chamber or chambers in which method 200 may be performed. Regardless, method 200 may optionally include delivering a semiconductor substrate to a processing region of a semiconductor processing chamber, such as processing chamber 100 described above, or other chambers that may include components as described above. The substrate may be deposited on a substrate support, which may be a pedestal such as substrate support 104, and which may reside in a processing region of the chamber, such as processing volume 120 described above.

As illustrated in FIG. 3A, a substrate on which several operations have been performed may be substrate 305 of a structure 300, which may show a partial view of a substrate on which semiconductor processing may be performed. It is to be understood that structure 300 may show only a few top layers during processing to illustrate aspects of the present technology. The substrate 305 may include a material 310 in which one or more features 315 may be formed. Substrate 305 may be any number of materials used in semiconductor processing. The substrate material may be or include silicon, germanium, dielectric materials including silicon oxide or silicon nitride, metal materials, or any number of combinations of these materials, which may be the substrate 305, or materials formed in structure 300. Features 315 may be characterized by any shape or configuration according to the present technology. In some embodiments, the features may be or include a trench structure or aperture formed within the substrate 305.

Although the features 315 may be characterized by any shapes or sizes, in some embodiments the features 315 may be characterized by higher aspect ratios, or a ratio of a depth of the feature to a width across the feature. For example, in some embodiments features 315 may be characterized by aspect ratios greater than or about 1:1, and may be characterized by aspect ratios greater than or about 5:1, greater than or about 10:1, greater than or about 15:1, greater than or about 20:1, greater than or about 30:1, greater than or about 40:1, greater than or about 50:1, greater than or about 60:1, greater than or about 70:1, greater than or about 80:1, greater than or about 90:1, or greater. Additionally, the features may be characterized by narrow widths or diameters across the feature including between two sidewalls, such as a dimension less than or about 100 nm, and may be characterized by a width across the feature of less than or about 90 nm, less than or about 80 nm, less than or about 70 nm, less than or about 60 nm, less than or about 50 nm, less than or about 40 nm, less than or about 30 nm, or less. Further, the features may be characterized by a depth of greater than or about 100 nm, and may be characterized by a depth of greater than or about 250 nm, greater than or about 500 nm, greater than or about 750 nm, greater than or about 1 μm, greater than or about 1.5 μm, greater than or about 2 μm, greater than or about 2.5 μm, greater than or about 3 μm, greater than or about 3.5 μm, greater than or about 4 μm, greater than or about 4.5 μm, greater than or about 5 μm, or more.

Method 200 may gap filling materials for semiconductor structures. However, to prevent the formation of a seam or a void in the gap fill material within the feature, which may occur in conventional plasma-enhanced atomic layer deposition (PEALD) processes, method 200 may include non-conformal poisoning to reduce or prevent deposition of silicon-containing material. As such, method 200 may include providing a poisoning precursor to the processing region at operation 205. At optional operation 210, method 200 may include forming plasma effluents of the poisoning precursor. Operation 215 may include contacting the substrate 305 with the poisoning precursor or, if formed, the plasma effluents thereof. As illustrated in FIG. 3B, the contacting may form a non-conformal poisoning material 320 the substrate 305 that may partially line the feature 315. In embodiments, the non-conformal poisoning material 320 may be discontinuous. Depending on the poisoning precursor used, in embodiments, the non-conformal poisoning material 320 may be a carbon-containing material. Subsequent to forming the non-conformal poisoning material 320, method 200 may include performing a silicon-containing atomic layer deposition (ALD) or PEALD process at operation 220 as illustrated in FIG. 3C.

As shown in FIG. 2, the operations of the non-conformal poisoning and ALD or PEALD process may be repeated at operation 225. The operations may be repeated any number of times in cycles to fill features 315 in embodiments of the present technology. As shown in FIGS. 3D-3E, the operations of the non-conformal poisoning and ALD or PEALD process may fill features 315 with silicon-containing material 325. For example, the operations may be repeated for a second cycle, a third cycle, a fourth cycle, a fifth cycle, a sixth cycle, a seventh cycle, or any number of cycles, depending on an amount of deposition per cycle and/or aspect ratio/depth of the features 315, necessary to completely fill the features 315 with silicon-containing material 325.

The poisoning precursor provided to the processing region at operation 205 may be or include a carbon-containing precursor, such as a hydrocarbon. For example, the carbon-containing precursor may be or include acetylene (C₂H₂), butene (C₄H₈), propane (C₃H₈), hexane (C₄H₁₀), pentane (C₅H₁₂), or any other carbon-containing materials that may be used or useful in semiconductor processing. The poisoning precursor may be provided with one or more diluents or carrier gases such as an inert gas or other gas delivered with the poisoning precursor.

In embodiments, a flow rate of the poisoning precursor, such as the carbon-containing precursor, may be selected to provide a desired amount of non-conformal poisoning material 320. More specifically, at higher flow rates of the poisoning precursor, a greater amount of non-conformal poisoning material 320 may be formed. Similarly, at higher flow rates of the poisoning precursor, the non-conformal poisoning material 320 may extend further into the features 315. In embodiments, the flow rate of the poisoning precursor may be greater than or about 100 sccm, and may be greater than or about 250 sccm, greater than or about 500 sccm, greater than or about 750 sccm, greater than or about 1,000 sccm, greater than or about 1,250 sccm, greater than or about 1,500 sccm, greater than or about 1,750 sccm, greater than or about 2,000 sccm, or more. However, higher flow rates may form excessive non-conformal poisoning material 320 that may slow the gap filling. As such, the flow rate of the poisoning precursor may be less than or about 2,000 sccm, and may be less than or about 1,750 sccm, less than or about 1,500 sccm, less than or about 1,250 sccm, less than or about 1,000 sccm, less than or about 750 sccm, less than or about 500 sccm, less than or about 250 sccm, or less.

In subsequent cycles of operations 205-220, the flow rate of the poisoning precursor may be maintained. However, the flow rate of the poisoning precursor may alternatively be reduced in subsequent cycles of operations 205-220 to reduce the amount of non-conformal poisoning material 320 extending into the features 315. If the flow rate of the poisoning precursor is not eventually reduced, the conformal poisoning material 320 may begin to form on the previously deposited silicon-containing material 325, which may reduce or prevent additional deposition of silicon-containing material 325.

Some embodiments may include forming plasma effluents of the poisoning precursor at optional operation 210. The power applied during deposition may be a lower power plasma, which may reduce dissociation and deposition rate. Accordingly, in some embodiments a plasma power source may deliver a plasma power to the faceplate, chamber, or substrate support of less than or about 5,000 W, and may deliver a power of less than or about 4,500 W, less than or about 4,000 W, less than or about 3,500 W, less than or about 3,000 W, less than or about 2,500 W, less than or about 2,000 W, less than or about 1,500 W, less than or about 1,000 W, less than or about 500 W, or less.

After forming the non-conformal poisoning material 320 for a period of time, method 200 may include halting a flow of the poisoning precursor. The period of time may be sufficient to form the non-conformal poisoning material 320 to reduce or prevent the deposition of material at upper portions of the feature 315. By reducing or preventing the deposition of material at upper portions of the feature 315, the deposition of silicon-containing material 325 may proceed from in a bottom-up, zipper-like fashion. This type of deposition may reduce or prevent formation of a seam or a void. As illustrated in FIG. 3B, a thickness of the non-conformal poisoning material 320 may taper to a reduced thickness as the non-conformal poisoning material 320 extends into the feature 315.

As previously discussed, subsequent to forming the non-conformal poisoning material 320, method 200 may include performing a silicon-containing ALD or PEALD process at operation 220. The silicon-containing ALD or PEALD process may include a layer by layer deposition of silicon-containing material 325. The silicon-containing ALD or PEALD process may include a first precursor dose, such as a silicon-containing precursor dose or an oxygen-containing precursor dose. In PEALD processes, plasma effluents of the first precursor dose may be formed. The first precursor dose or, if formed, plasma effluents thereof may be adsorbed, such as through chemisorption, on the substrate 305 or material 310. A first purge may be performed to remove excess amounts of the first precursor dose, such as the first precursor that has not been absorbed on the substrate 305 or material 310.

After the first purge, the silicon-containing ALD or PEALD process may include a second precursor dose, such as a silicon-containing precursor dose or an oxygen-containing precursor (the opposite of the first precursor dose). In PEALD processes, plasma effluents of the second precursor dose may be formed. The second precursor or, if formed, plasma effluents thereof may react with the first precursor dose adsorbed on the substrate 305 or material 310. The reaction between the first precursor dose and the second precursor dose may form the silicon-containing material 325. A second purge may be performed to remove excess amounts of the second precursor dose, such as the second precursor that has not reacted with the first precursor to form silicon-containing material 325.

During the oxygen-containing precursor dose, whether the first precursor dose or second precursor does, the non-conformal poisoning material 320 may be at least partially, if not fully, removed. The oxygen-containing precursor, or plasma effluents thereof, may react with the carbon-containing material of the non-conformal poisoning material 320 to form volatiles that may be purged from the processing region. For example, the oxygen-containing precursor may react with the carbon-containing material of the non-conformal poisoning material 320 to form carbon monoxide (CO), carbon dioxide (CO₂), or other gaseous carbon-containing materials that may be pumped out of the processing region. The reduction or removal of the non-conformal poisoning material 320 may advantageously allow the deposition to proceed in a bottom-up, zipper-like fashion. Thus, as illustrated in FIGS. 3B-3C, the silicon-containing ALD or PEALD process may selectively deposit silicon-containing material 325 on sidewalls of the feature 315. Additionally, the silicon-containing material 325 may not deposit on the non-conformal poisoning material 320, which may be removed. In embodiments where the operations are repeated, a reduced amount of non-conformal poisoning material 320 may be deposited in a subsequent cycle, such as by reducing the flow rate of the poisoning precursor (or adjusting other processing conditions), to allow deposition to proceed upwards in the feature 315.

Although any silicon-containing precursor may be used, in some embodiments, the silicon-containing precursor(s) may be used during the silicon-containing ALD or PEALD process may include, but are not limited to, silane (SiH₄), disilane (Si₂H₆), trisilane (Si₃H₈), tetrasilane (Si₄H₁₀), pentasilane (SisH₁₂), or other organosilanes including cyclohexasilanes, an aminosilane, silicon tetrafluoride (SiF₄), silicon tetrachloride (SiCl₄), dichlorosilane (SiH₂Cl₂), tetraethyl orthosilicate (TEOS), as well as any other silicon-containing materials that may be used or useful in semiconductor processing. Similarly, although any oxygen-containing precursor may be used, in some embodiments, the oxygen-containing precursor(s) may be used during the silicon-containing ALD or PEALD process may include, but are not limited to, diatomic oxygen (O₂), nitrous oxide (N₂O), hydrogen peroxide (H₂O₂), or other oxygen-containing materials that may be used or useful in semiconductor processing.

If plasma-enhanced, a plasma power source may deliver a plasma power to the faceplate, chamber, or substrate support of greater than or about 100 W, and may deliver a power of greater than or about 250 W, greater than or about 500 W, greater than or about 1,000 W, greater than or about 1,500 W, greater than or about 2,000 W, greater than or about 2,500 W, greater than or about 3,000 W, greater than or about 3,500 W, greater than or about 4,000 W, greater than or about 4,500 W, greater than or about 5,000 W, greater than or about 5,500 W, greater than or about 6,000 W, greater than or about 7,000 W, greater than or about 8,000 W, or more. The plasma power may impact deposition rate, conformality, and/or quality of the deposited material. For example, higher plasma powers may deposit a higher quality material and/or may deposit material at an increased deposition rate, but may result in damage to other materials or structures on the substrate 305.

After the second purge, the first precursor dose, first purge, and second precursor dose, and second purge may be repeated any number of times to continue forming silicon-containing material 325. However, to maintain a bottom-up, zipper-like fashion of the gap fill, method 200 may include intermittently performing the poisoning of operations 205-215.

Temperature may impact operations of the present technology. For example, the method 200 may be performed at a temperature less than or about 600° C., and may be performed at a temperature less than or about less than or about 575° C., less than or about 550° C., less than or about 525° C., less than or about 500° C., less than or about 475° C., less than or about 450° C., less than or about 425° C., less than or about 400° C., less than or about 375° C., less than or about 350° C., less than or about 325° C., less than or about 300° C., or less. Additionally, the method 200 may be performed at a temperature greater than or about 100° C., and may be performed at a temperature greater than or about 300° C., and may be performed at a temperature greater than or about 325° C., greater than or about 350° C., greater than or about 375° C., greater than or about 400° C., greater than or about 425° C., greater than or about 450° C., greater than or about 475° C., greater than or about 500° C., greater than or about 525° C., greater than or about 550° C., greater than or about 575° C., greater than or about 600° C., or more. The temperature may be maintained in any of these ranges throughout the method 200, including during the poisoning and the deposition. However, it is also contemplated that the temperature may be adjusted between operations.

Pressure may also impact operations of the present technology. For example, the method 200 may be performed at a pressure less than or about 50 Torr, and may be performed at a pressure less than or about 40 Torr, less than or about 30 Torr, less than or about 20 Torr, less than or about 15 Torr, less than or about 10 Torr, less than or about 8 Torr, less than or about 6 Torr, less than or about 5 Torr, less than or about 4 Torr, less than or about 3 Torr, less than or about 2 Torr, less than or about 1 Torr, or less.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a carbon-containing precursor” includes a plurality of such precursors, and reference to “the carbon-containing material” includes reference to one or more materials and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing a carbon-containing precursor to a processing region of a semiconductor processing chamber, wherein a substrate is disposed in the processing region, and wherein the substrate defines a feature;
contacting the substrate with the carbon-containing precursor, wherein the contacting forms a carbon-containing material on the substrate that partially lines the feature;
performing a silicon-containing atomic layer deposition (ALD) process, wherein the silicon-containing ALD process deposits a silicon-containing material at a bottom portion of the feature; and
repeating the operations to fill the feature with silicon-containing material.

2. The semiconductor processing method of claim 1, wherein the carbon-containing precursor comprises a hydrocarbon.

3. The semiconductor processing method of claim 1, wherein the feature is characterized by an aspect ratio of greater than or about 10:1.

4. The semiconductor processing method of claim 1, wherein the feature is characterized by a depth of greater than or about 1 μm.

5. The semiconductor processing method of claim 1, further comprising:
forming plasma effluents of the carbon-containing precursor.

6. The semiconductor processing method of claim 1, wherein the carbon-containing material is discontinuous.

7. The semiconductor processing method of claim 1, wherein the silicon-containing ALD process is plasma-enhanced.

8. The semiconductor processing method of claim 1, wherein the silicon-containing ALD process removes the carbon-containing material.

9. The semiconductor processing method of claim 1, wherein the silicon-containing material is not deposited on the carbon-containing material.

10. The semiconductor processing method of claim 1, wherein the silicon-containing material fills the feature from bottom-up.

11. A semiconductor processing method comprising:
i) providing a carbon-containing precursor to a processing region of a semiconductor processing chamber, wherein a substrate is disposed in the processing region, and wherein the substrate defines a feature;
ii) forming plasma effluents of the carbon-containing precursor;
iii) contacting the substrate with the carbon-containing precursor, wherein the contacting forms a carbon-containing material that is discontinuous on the substrate that partially lines the feature; and
iv) performing a silicon-containing atomic layer deposition (ALD) process, wherein the silicon-containing ALD process deposits a silicon-containing material at a bottom portion of the feature, and wherein the silicon-containing ALD process comprises:
providing a silicon-containing precursor to the processing region;
forming plasma effluents of the silicon-containing precursor;
contacting the substrate with the silicon-containing precursor;
providing an oxygen-containing precursor to the processing region;
forming plasma effluents of the oxygen-containing precursor; and
contacting the substrate with the oxygen-containing precursor.

12. The semiconductor processing method of claim 11, wherein the feature is characterized by a width of less than or about 100 nm.

13. The semiconductor processing method of claim 11, wherein the silicon-containing material is selectively deposited on sidewalls of the feature.

14. The semiconductor processing method of claim 11, wherein contacting the substrate with the oxygen-containing precursor removes the carbon-containing material.

15. The semiconductor processing method of claim 11, further comprising:
v) repeating operations i) through iv) to fill the feature with the silicon-containing material for a plurality of cycles.

16. The semiconductor processing method of claim 15, further comprising:
reducing a flow rate of the carbon-containing precursor during subsequent cycles.

17. The semiconductor processing method of claim 11, wherein the silicon-containing ALD process further comprises:
purging the silicon-containing precursor prior to providing the oxygen-containing precursor.

18. A semiconductor processing method comprising:
i) providing a hydrocarbon precursor to a processing region of a semiconductor processing chamber, wherein a substrate is disposed in the processing region, and wherein the substrate defines a feature characterized by an aspect ratio greater than or about 30:1;
ii) contacting the substrate with the hydrocarbon precursor, wherein the contacting forms a carbon-containing material that is non-conformal on the substrate that partially lines the feature;
iii) performing a silicon-containing atomic layer deposition (ALD) process, wherein the silicon-containing ALD process deposits a silicon-containing material at a bottom portion of the feature; and
iv) repeating operations i) through iii) to fill the feature with silicon-containing material.

19. The semiconductor processing method of claim 18, wherein the hydrocarbon precursor comprises hexane (C₆H₁₄) or acetylene (C₂H₂).

20. The semiconductor processing method of claim 18, wherein the silicon-containing ALD process comprises contacting the substrate with an oxygen-containing precursor, and wherein the contacting removes the carbon-containing material.
